(19) United States
(12) Patent Application Publication
(10) Pub. No.: US 2012/0228110 A1
(43) Pub. Date: Sep. 13, 2012

(54) TRANSPARENT ELECTRODE ELEMENT, INFORMATION INPUT DEVICE, AND ELECTRONIC APPARATUS

(75) Inventors: Hidetoshi Takahashi, Miyagi (JP); Mikihasa Mizuno, Miyagi (JP); Masayuki Ishiwata, Tochigi (JP)

(73) Assignee: Sony Corporation, Tokyo (JP)

(21) Appl. No.: 13/409,442

(22) Filed: Mar. 1, 2012

(30) Foreign Application Priority Data
Mar. 8, 2011 (JP) 2011-050060

(51) Int. Cl. H03K 17/975; H05K 1/00

(52) U.S. Cl. 200/600; 174/250

(57) ABSTRACT

A transparent electrode element includes: a base substrate; a transparent conductive film which is formed on the base substrate; an electrode region which is formed using the transparent conductive film; and an insulation region which is a region adjacent to the electrode region and in which the transparent conductive film is separated in independent island shapes by groove patterns extending in random directions.

### BACKGROUND

The present technology relates to a transparent electrode element, an information input device, and an electronic apparatus, and more particularly, to a transparent electrode element having a patterned electrode region, an information input device using the transparent element, and an electronic apparatus in which the transparent electrode element is provided in a display panel.

An information input device (a so-called touch panel) disposed on a display surface side of a display panel has a configuration in which an electrode pattern extending in the X direction and an electrode pattern extending in the Y direction are arranged in an insulated state on a transparent substrate. The electrode patterns are formed using a transparent conductive film made of metal oxide such as indium tin oxide (ITO) or a transparent conductive film in which a metal nanowire is integrated.

In the information input device with such a configuration, a given film thickness is necessary when the resistance value of the electrode patterns formed using the transparent conductive film is set to be low. For this reason, since the electrode pattern is easily viewed when the information input device is viewed from the outside, visibility of a display image displayed on the display panel provided with the information input device may deteriorate.

Accordingly, configurations have been suggested in which dummy electrodes in a floating state between the electrode patterns are provided to suppress the contrast of the electrode patterns so as not to notice the presence of the electrode patterns (for example, see Japanese Unexamined Patent Application Publication No. 2008-129708 and Japanese Unexamined Patent Application Publication No. 2010-2958).

### SUMMARY

However, even in the information input device in which the above-described dummy electrodes are provided, it is difficult for the electrode pattern not to be completely noticed, since a region where transparent conductive film is removed is continuously formed between the electrode pattern and the dummy electrode along the electrode pattern.

It is desirable to provide a transparent electrode element and an information input device capable of reducing a visibility of an electrode region formed of a transparent conductive film up to the limit. Further, it is desirable to provide an electronic apparatus capable of realizing a high-definition display in a configuration in which the electrode region formed of the transparent conductive film is patterned on a display surface side of a display panel.

According to an embodiment of the present technology, there is provided a transparent electrode element including: a base substrate; a transparent conductive film which is formed on the base substrate; an electrode region which is formed using the transparent conductive film. The transparent electrode element further includes an insulation region which is a region adjacent to the electrode region and in which the above-described transparent conductive film is separated in independent island shapes by groove patterns extending in random directions.

According to other embodiments of the present technology, there are provided an information input device including the transparent electrode element with the above-described configuration and an electronic apparatus in which the transparent electrode element with the above-described configuration is disposed on a display surface side of a display panel.

The contrast of the electrode region and the insulation region is suppressed so as to be small by disposing the transparent conductive film separated in independent island shapes in the insulation region adjacent to the electrode region. In particular, the transparent conductive film in the insulation region is separated by groove patterns extending in random directions. Therefore, moire is prevented from being generated, the continuous groove patterns are formed along the electrode region in the boundary between the insulation region and the electrode region, and the contour of the electrode region is not visually noticeable. Further, since the coverage ratio of the transparent conductive film in the insulation region is adjusted in a broad range by the width of the groove pattern, the insulation region with the high coverage ratio of the transparent conductive film can be formed. Thus, the contrast can be made to be small in the electrode region and the insulation region.

According to the embodiments of the present technology, it is possible to decrease the visibility of the electrode region up to the limit by suppressing the contrast of the electrode region and the insulation region so as to be small in the transparent electrode element including the electrode region formed using the transparent conductive film and the information input device. Further, in the electronic apparatus in which the electrode region formed using the transparent conductive film is pattern-formed in the side of the display surface of the display panel, the display characteristics of the display panel are prevented from being affected by the electrode region, thereby achieving a high-definition display.

### BRIEF DESCRIPTION OF THE DRAWINGS

FIG. 1 is a plan view illustrating the configuration of a transparent electrode element according to a first embodiment;

FIGS. 2A and 2B are an expanded plan view and a sectional view illustrating main units in the configuration of the transparent electrode element according to the first embodiment, respectively;

FIGS. 3A and 3B are an expanded plan view and a sectional view illustrating main units in the configuration of a transparent electrode element according to a second embodiment;

FIG. 4 is a schematic diagram (part 1) for describing an algorithm of generating a random pattern;

FIG. 5 is a flowchart (part 1) for describing an algorithm of generating a random pattern;

FIG. 6 is a schematic diagram (part 2) for describing the algorithm of generating the random pattern;

FIG. 7 is a flowchart (part 2) for describing an algorithm of generating a random pattern;

FIG. 8 is a schematic diagram (part 3) for describing the algorithm of generating the random pattern;

FIGS. 9A and 9B are schematic diagrams illustrating images of a method of generating the random pattern.

FIGS. 10A and 10B are diagrams illustrating the layouts of hole patterns in an electrode region generated based on the generated pattern;

FIGS. 11A to 11C are plan views illustrating an order of generation of a groove pattern in an insulation region based on the generated pattern;

FIG. 12 is a plan view illustrating a change in the width of the groove pattern;

FIGS. 13A and 13B are diagrams illustrating the configuration of an original disk used in a first method of manufacturing the transparent electrode element according to an embodiment of the present technology;

FIGS. 14A and 14B are sectional views illustrating steps of the first method of manufacturing the transparent electrode element using the original disk according to the embodiment of the present technology;

FIGS. 15A to 15D are sectional views illustrating a second method of manufacturing a transparent electrode element according to an embodiment of the present technology;

FIGS. 16A to 16D are sectional views of Modifications 1 to 4 of the transparent electrode element of the embodiment of the present technology;

FIG. 17 is a diagram illustrating an example of the configuration of an information input device including the transparent electrode element according to an embodiment of the present technology;

FIG. 18 is a perspective view illustrating the configuration of a display apparatus (electronic apparatus) including the information input apparatus;

FIG. 19 is a perspective view illustrating a television (electronic apparatus) including a display unit;

FIGS. 20A and 20B are perspective views illustrating a digital camera (electronic apparatus) including the display unit;

FIG. 21 is a perspective view illustrating a notebook-type personal computer (electronic apparatus) including the display unit;

FIG. 22 is a perspective view illustrating a video camera (electronic apparatus) including the display unit;

FIG. 23 is a front view illustrating a portable terminal apparatus (electronic apparatus) including the display unit; and

FIG. 24 is a plan view illustrating the patterns of an electronic region and an insulation region according to Examples 1 to 3.

### DETAILED DESCRIPTION OF EMBODIMENTS

Hereinafter, embodiments of the present technology will be described in the following order with reference to the drawings.

1. First Embodiment (Transparent Electrode Element in Which Random Pattern Is Formed in Electrode Region and Insulation Region)

2. Second Embodiment (Transparent Electrode Element in Which Random Pattern Is Formed Only in Insulation Region)

3. Method of Generating Pattern of Transparent Electrode Element

4. First Method of Manufacturing Transparent Electrode Element (Method of Using Original Disk)

5. Second Method of Manufacturing Transparent Electrode Element (Method of Applying Pattern Etching)

6. Modifications 1 to 4 of Transparent Electrode Element

7. Third Embodiment (Information Input Device Using Transparent Electrode Element)

8. Fourth Embodiment (Display Apparatus Using Information Input Device)

9. Fifth Embodiment (Application of Electronic Apparatus)

### 1. First Embodiment

Transparent Electrode Element in which Random Pattern is Formed in Electrode Region and Insulation Region

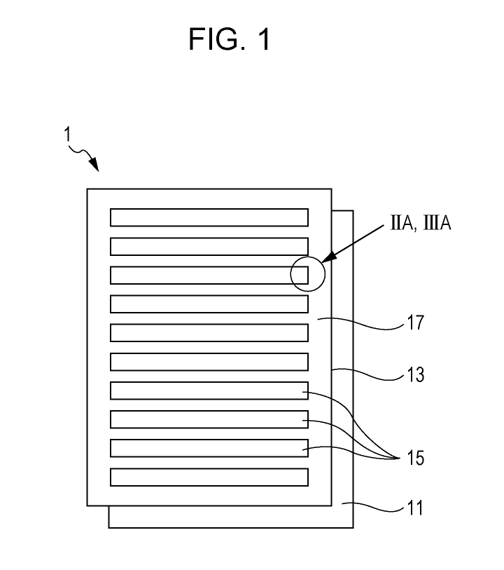

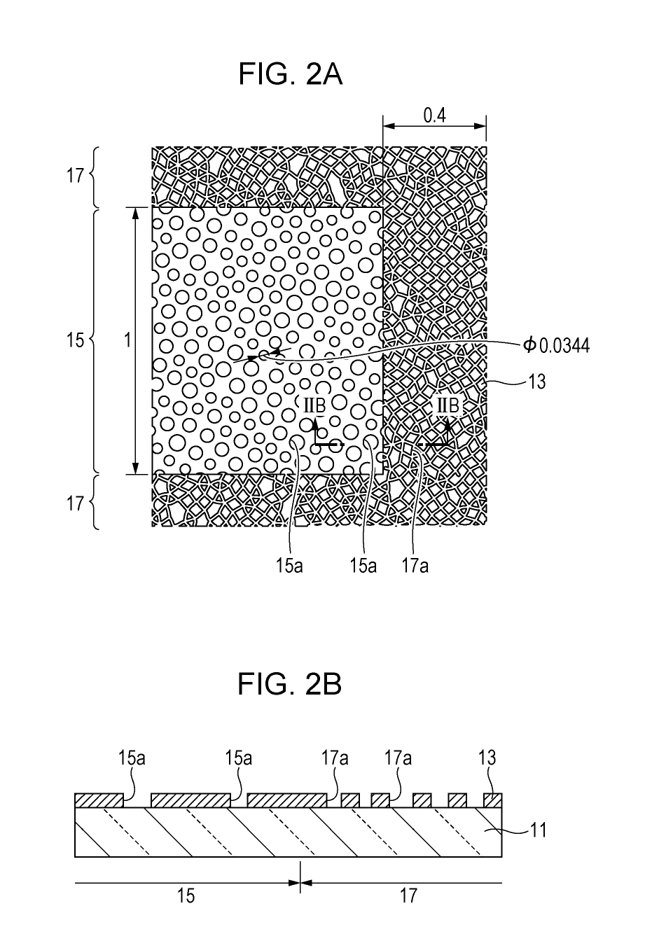

FIG. 1 is a plan view illustrating the configuration of a transparent electrode element according to a first embodiment. FIG. 2A is an expanded plan view illustrating an expanded section IIA of FIG. 1 and FIG. 2B is a sectional view taken along the line IIB-IIB of the expanded plan view. For example, a transparent electrode element 1 shown in the drawings is a transparent electrode element appropriately disposed on a display surface side of a display panel. The transparent electrode element 1 has the following configuration.

That is, the transparent electrode element 1 includes a base substrate 11 and a transparent conductive film 13 disposed on the base substrate 11. Further, the transparent electrode element 1 includes a plurality of electrode regions 15 formed using a transparent conductive film 13 and an insulation region 17 disposed in the vicinity of the electrode regions 15. The transparent conducive film 13 is also disposed in the insulation region 17. Hereinafter, each member and region will be described in detail.

Base Substrate 11

The base substrate 11 is formed of, for example, a transparent material such as glass or plastic. Examples of the glass include soda-lime glass, lead glass, hard glass, quartz glass, and liquid crystal glass. Examples of the plastic include triacetylcellulose (TAC), polyester (TPEE), polyethylene terephthalate (PET), polyethylene naphthalate (PEN), polyimide (PI), polyamide (PA), aramid, polyethylene (P), polyacrylate, polyethersulphone, polysulphone, polypropylene (PP), diacetyle cellulose, polyvinyl chloride, acrylate resin (PMMA), polycarbonate (PC), epoxy resin, urea resin, urethane resin, melamine resin, cyclic olefin polymer (COP), norbornene-based thermoplastic resin.

The thickness of the base substrate 11 made of glass is preferably in the range of 20 μm to 10 mm, but is not limited to this range. The thickness of the base substrate 11 made of plastic is preferably is in the range of 20 μm to 500 μm, but is not limited to this range.

### Transparent Conductive Film 13

Examples of the material of the transparent conductive film 13 include metal oxides such as indium tin oxide (ITO), zinc oxide, indium oxide, antimony-containing tin oxide, fluorine-containing tin oxide, aluminum-containing zinc oxide, gallium-containing zinc oxide, silicon-containing zinc oxide, zinc oxide-tin oxide base, indium oxide-tin oxide base, and zinc oxide-indium oxide-magnesium oxide base. Further, examples of the material of the transparent conductive film 13 include metals such as copper, silver, gold, platinum, palladium, nickel, tin, cobalt, rhodium, iridium, iron, ruthenium, osmium, manganese, molybdenum, tungsten, niobium, tantalum, titanium, bismuth, antimony, lead, and alloys thereof.

As the material of the transparent conductive film 13, a composite material in which carbon nanotubes are dispersed in a binder material may be used. Alternatively, a material preventing diffused reflection of light on the surface using a metal nanowire or by adsorbing a colored compound to the metal nanowire may be used. Alternatively, a conductive polymer of a polymer (copolymer) formed of substituted-polyaniline, non-substituted-polyaniline, polypyrrole, polythiophene, or one or two selected therefrom may be used. A material formed of compounding two or more thereof may be used.

Examples of a method of forming the transparent conductive film 13 include a PVD method such as a sputtering method, a vacuum deposition method, or an ion plating method, a CVD method, a coating method, and a printing method. The thickness of the transparent conductive film 13 is appropriately selected so that the surface resistance is 1000Ω/□ or less before the patterning (a state where the transparent conductive film is formed on the entire surface of the base substrate 11).

### Electrode Region 15

The electrode region 15 is configured as a region where a plurality of hole patterns 15a are formed at random in the transparent conductive film 13. That is, the electrode region 15 is formed using the transparent conductive film 13 and the hole patterns 15a with random sizes are arranged at random as random patterns. Here, for example, circular hole patterns 15a with various diameters are arranged independently in the transparent conductive film 13, thereby ensuring the conductivity in each electrode region 15 as a whole.

In the electrode region 15, the coverage ratio of the transparent conductive film 13 is adjusted by the range of the diameter of each hole pattern 15a. The coverage ratio is set for each material and each thick film of the transparent conductive film 13 to the extent that conductivity necessary in the electrode region 15 is obtained. The adjustment of the coverage ratio by the range of the diameter of each hole pattern 15a will be described later in the item of “Method of Generating Random Pattern.”

The shapes of the hole patterns 15a formed in the electrode region 15 are not limited to the circle. One or two kinds of shapes selected from a group of, for example, a circular shape, an elliptical shape, a shape obtained by partially cutting a circular shape, a shape obtained by partially cutting an elliptical shape, a polygonal shape, a chamfered polygonal shape, and an indefinite shape may be used as the shapes of the hole patterns 15a, as long as the shapes of the hole patterns 15a are not visually noticeable and are not periodic.

Further, the electrode region 15 may be configured such that the transparent conductive film 13 is formed as strip-shaped patterns by reversing groove patterns 17a in the insulation region 17 and the hole patterns 15a separated by the strip-shaped patterns are arranged. In this case, the electrode region 15 is in a state where the strip-shaped patterns formed of the transparent conductive film 13 extend in random directions. The strip-shaped patterns extending in the random directions are also random patterns.

However, when each hole pattern 15a has a large size, the shape can visually be noticed. Therefore, it is desirable to avoid a form in which there are a plurality of shapes in which the hole patterns 15a and parts of the transparent conductive film 13 are continuous from any point in any direction by 100 μm or more in the electrode region 15. For example, when the hole patterns 15a have a circular shape, the diameter is preferably less than 100 μm.

### Insulation Region 17

The insulation region 17 is a region disposed near the electrode region 15. The insulation region 17 is embedded between the electrode regions 15 and is disposed to insulate the electrode regions 15 from each other. The transparent conductive film 13 formed in the insulation region 17 is a separated in an independent island shape by the groove patterns 17a extending in random directions. That is, the insulation region 17 is formed using the transparent conductive film 13 and the island-shaped patterns formed by separating the transparent conductive film 13 by the groove patterns 17a extending in the random directions are disposed as random patterns. The island-shaped patterns (that is, the random patterns) are separated in random polygonal shapes by the groove patterns 17a extending in the random directions. The groove patterns 17a themselves extending in the random directions are random patterns.

The respective groove patterns 17a formed in the insulation region 17 extend in a random direction in the insulation region 17 and are formed such that the widths (referred to as line widths) perpendicular to the extension direction are the same as each other. In the insulation region 17, the coverage ratio of the transparent conductive film 13 is adjusted by the line width of each groove pattern 17a. The coverage ratio is set to the same extent of the coverage ratio of the transparent conductive film 13 in the electrode region 15. Here, the same extent refers to the extent that the regions 15 and 17 may not be noticed at each pitch of the electrode region 15 and the insulation region 17. The adjustment of the coverage ratio by the line width of the groove pattern 17a will be described later in the item of “Method of Generating Random Pattern.”

However, when the sizes of the island shapes separated by the groove patterns 17a are too large, the shape of the transparent conductive film 13 may be visually noticeable. Therefore, it is desirable to avoid a form in which there are a plurality of shapes in which the parts of the transparent conductive film 13 are continuous from any point in any direction by 100 μm or more in the electrode region 15.

In the boundary between the electrode region 15 and the insulation region 17, the transparent conductive film 13 disposed between these regions 15 and 17 is disposed at random.

### Advantages of First Embodiment

In the transparent electrode element 1 with the above-described configuration, the coverage ratio of the transparent conductive film 13 is suppressed in the electrode regions 15 by forming the plurality of hole patterns 15a at random in the transparent conductive film 13 forming the electrode regions 15. On the other hand, the transparent conductive film 13 separated in the island shapes are disposed in the insulation regions 17 adjacent to the electrode regions 15. Thus, a difference in the coverage ratio of the transparent conductive film 13 is made to be small between the electrode region 15 and the insulation region 17. Accordingly, since the contrast between these regions 15 and 17 can be reduced, it is possible to reduce the visibility of the patterns of the electrode regions 15.

In particular, the hole patterns 15a are formed at random in the transparent conductive film 13 in the electrode region 15. Further, the transparent conductive film 13 in the insulation region 17 is separated by the groove patterns 17a extending in the random directions. Accordingly, moire is prevented from being generated. Further, the continuous groove pattern is not formed along the electrode region 15 in the boundary between the insulation region 17 and the electrode region 15 and the contour of the electrode region is not noticed.

As described later in the item of “3. Method of Generating Pattern of Transparent Electrode Element”, the coverage ratio of the transparent conductive film 13 in the insulation region 17 can be adjusted in a broad range by the width of the groove pattern 17a. Accordingly, the sheet resistance in the electrode region 15 can be suppressed so as to be small. Therefore, even when the thickness of the transparent conductive film 13 set to be thick, the insulation region 17 can be configured so that the coverage ratio of the transparent conductive film 13 is high. Accordingly, the contrast of the electrode region 15 can efficiently be reduced.

### 2. Second Embodiment

Transparent Electrode Element in which Random Pattern is Formed Only in Insulation Region

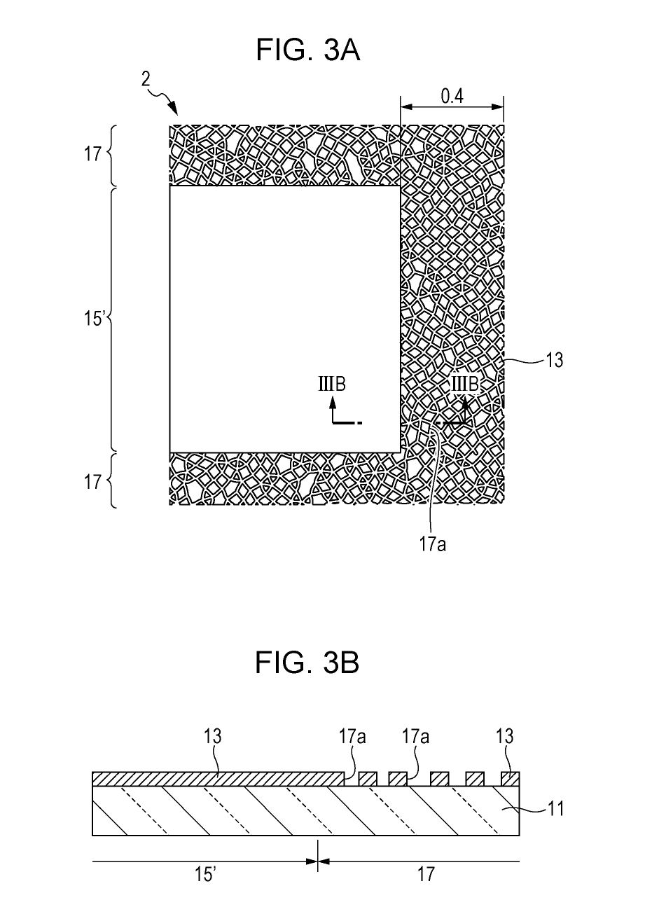

FIGS. 3A and 3B are expanded views illustrating the configuration of the transparent electrode element according to a second embodiment. FIG. 3A is an expanded plan view illustrating a section corresponding to the expanded section IIIA of FIG. 1. FIG. 3B is a sectional view taken along the line IIIB-IIIB of the expanded plan view of FIG. 3A. A transparent electrode element 2 shown in the drawings is different from the transparent electrode element 1 described with reference to FIGS. 2A and 2B in the first embodiment in that an electrode region 15′ is formed of a transparent conductive film 13 with a solid film shape. The remaining configuration is the same.

That is, in the electrode region 15′, the transparent conductive film 13 is formed in the solid film state in the electrode region 15′, and thus the coverage ratio of the transparent conductive film 13 is 100%. In the boundary between the electrode region 15′ and the insulation region 17, the transparent conductive film 13 disposed between these regions 15′ and 17 is disposed at random.

In this case, the configuration of the insulation region 17 is the same as that of the first embodiment, but the setting range of the coverage ratio of the transparent conductive film 13 in the insulation region 17 is larger than that of the first embodiment. Accordingly, the adjustment range of the line width of the groove pattern 17a used to adjust the coverage ratio is smaller than that of the first embodiment.

### Advantages of Second Embodiment

Even in the transparent electrode element 2 with the above-described configuration, the transparent conductive film 13 separated in the island shapes by the groove patterns 17a extending in the random directions is disposed in the insulation region 17 adjacent to the electrode region 15′. Thus, as in the first embodiment, moire is prevented from being generated, the contour of the electrode region 15′ is not noticed, and the sheet resistance in the electrode region 15′ is suppressed so as to be small. Therefore, even when the thickness of the transparent conductive film 13 is set to be thick, the insulation region 17 can be configured such that the coverage ratio of the transparent conductive film 13. Accordingly, the contrast of the electrode region 15′ can efficiently be reduced.

### 3. Method of Generating Pattern of Transparent Electrode Element

Next, a method of generating the pattern of the electrode region in the transparent electrode element 1 described in the first embodiment and a method of generating the pattern of the insulation region in the transparent electrode elements 1 and 2 described in the first and second embodiments, respectively will be described. The methods of generating the patterns described herein are just examples, and embodiments of the present technology are not limited to the methods of generating the patterns in the transparent electrode element.

### Method of Generating Random Pattern

First, a random pattern compatible in both a random disposition property and high-density filling property is generated by calculating the center coordinates of a circle and disposing the circle so that adjacent circles are normally adjacent when the radius of the circle is varied at random within the setting range. In this case, the random pattern disposed at random uniformly and highly densely can be obtained at the small calculation volume through the following algorithms (1) and (2).

(1) A circle with “a random diameter within a given range” is lined on the X axis so as to be adjacent. Necessary parameters are as follows:

Xmax: the maximum value of the X coordinate in a region where the circle is generated;

Yw: the maximum value of the Y coordinate from the center of the circle is set when the circle is disposed on the X axis;

Rmin: the minimum radius of the generated circle;

Ramx: the maximum radius of the generated circle;

Rnd: a random value obtained in the range of 0.0 to 1.0; and

Pn: a circle defined by the X coordinate value xn, the Y coordinate value yn, and the radius rn.

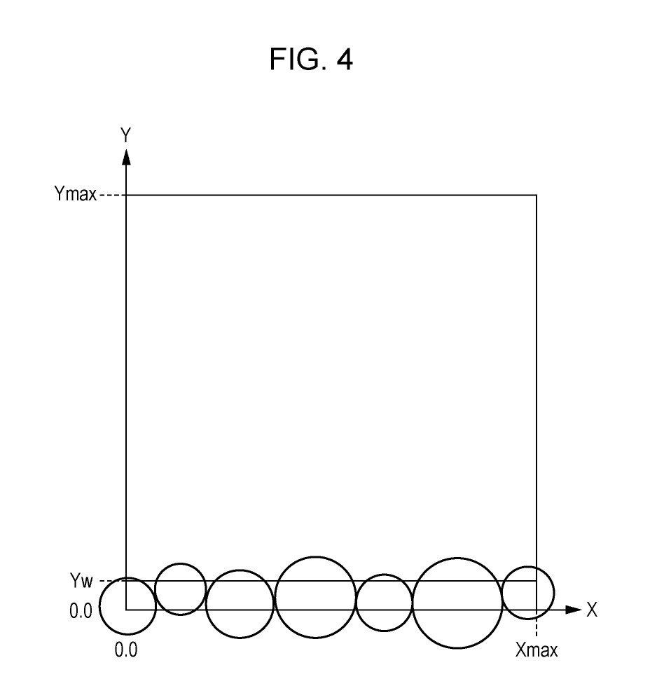

FIG. 4 is a schematic diagram for describing the above algorithm (1). As shown in FIG. 4, circles are arranged at random in one line by repeatedly arranging the circles, which are obtained by determining the value of the Y coordinate at random in the range of 0.0 to Rmin on the X coordinate and determining the radius at random in the range from Rmin to Rmax, so as to be adjacent to the existing circle.

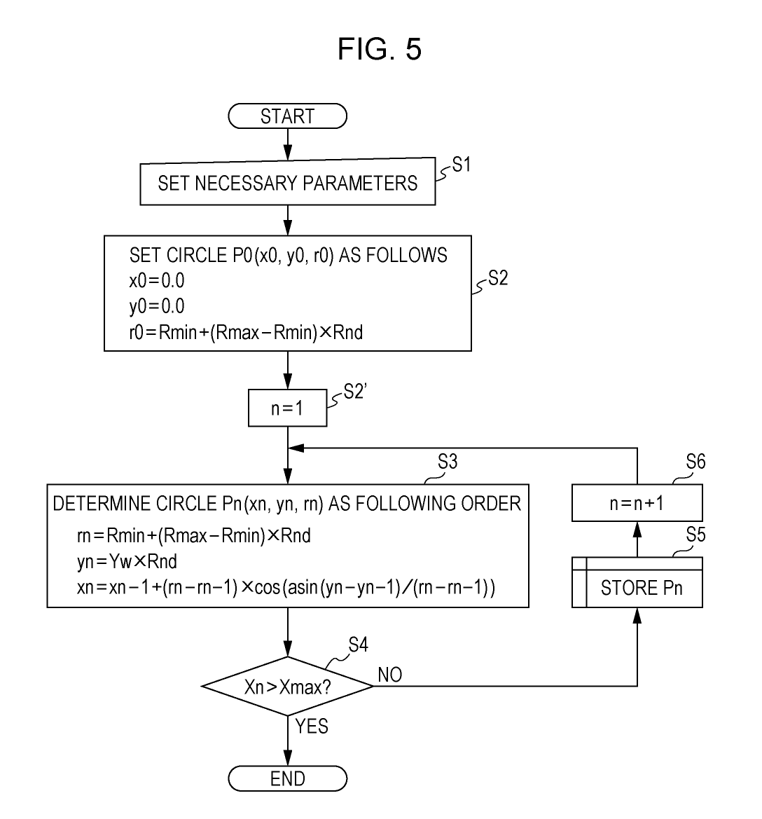

Hereinafter, the algorithm (1) will be described with reference to the flowchart of FIG. 5.

First, in step S1, the necessary parameters described in the algorithm (1) are set. Next, in step S2, a circle P0 (x0, y0, r0) is set as follows:

x0=0.0;

y0=0.0; and

r0=Rmin+(Rmax−Rmin)×Rnd.

Next, in step S2′, “n=1” is set.

Next, in step S3, a circle Pn (xn, yn, rn) is determined by the following equation.

rn=Rmin+(Rmax−Rmin)×Rnd.

yn=Yw×Rnd.

xn=xn−1+(rn−rn−1)×cos(a sin(yn−yn−1)/(rn−rn−1))

Next, in step S4, it is determined whether an expression of “Xn>Xmax” is satisfied. When it is determined in step S4 that the expression of “Xn>Xmax” is satisfied, the process ends. When it is determined in step S4 that the expression of “Xn>Xmax” is not satisfied, the process proceeds to step S5. In step S5, the circle Pn (xn, yn, rn) is stored. Next, in step S6, the value of n increases and the process proceeds to step S3.

(2) “Circles with a random radius” is determined, the circles are sequentially piled from the low side so as to be adjacent to two existing circles and not to be adjacent to the other circles. Necessary parameters are as follows:

Ymax: the maximum value of the Y coordinate in a region where the circle is generated;

Rmin: the minimum radius of the generated circle;

Rmax: the maximum radius of the generated circle;

Rfill: the minimum radius of a subsidiary circle set to improve a filling ratio;

Rnd: a random value obtained in the range of 0.0 to 1.0; and

Pn: a circle defined by the X coordinate value xn, the Y coordinate value yn, and the radius rn.

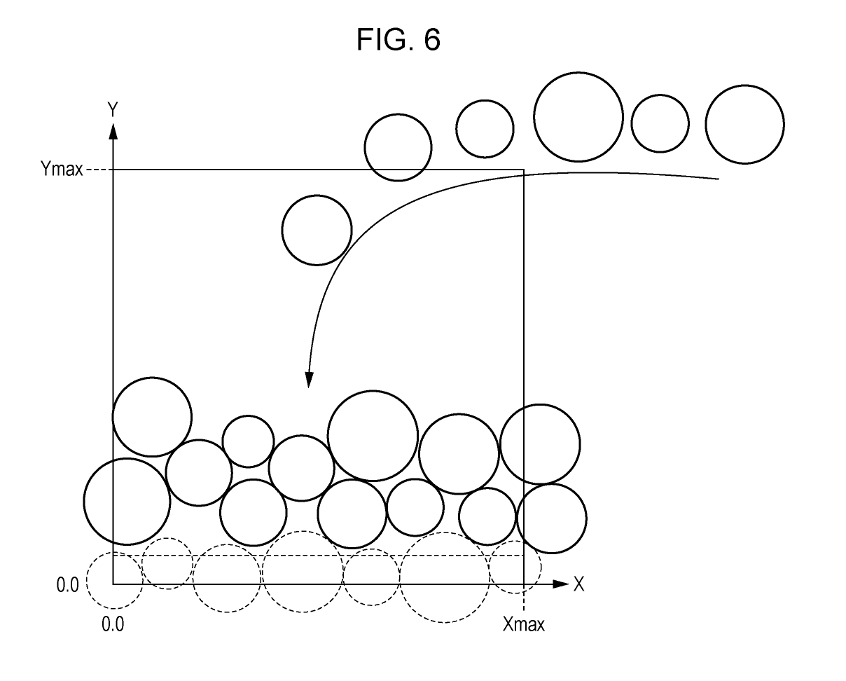

FIG. 6 is a schematic diagram for describing the above algorithm (2). As shown in FIG. 6, the circles with a random radius are determined at random in the range of Rmin to Rmax based on the circles (indicated by a dashed line), which are determined in the algorithm (1) and are arranged in one line on the X axis, and the circles are repeatedly arranged so as to be adjacent to other circles from the circles with the smaller Y coordinate. Rfill is set smaller than Rmin and a space is embedded to improve the filling ratio only when there is the space which is no embedded in the determined circle. When a circle smaller than Rmin is not used, an expression of “Rfill=Rmin” is set.

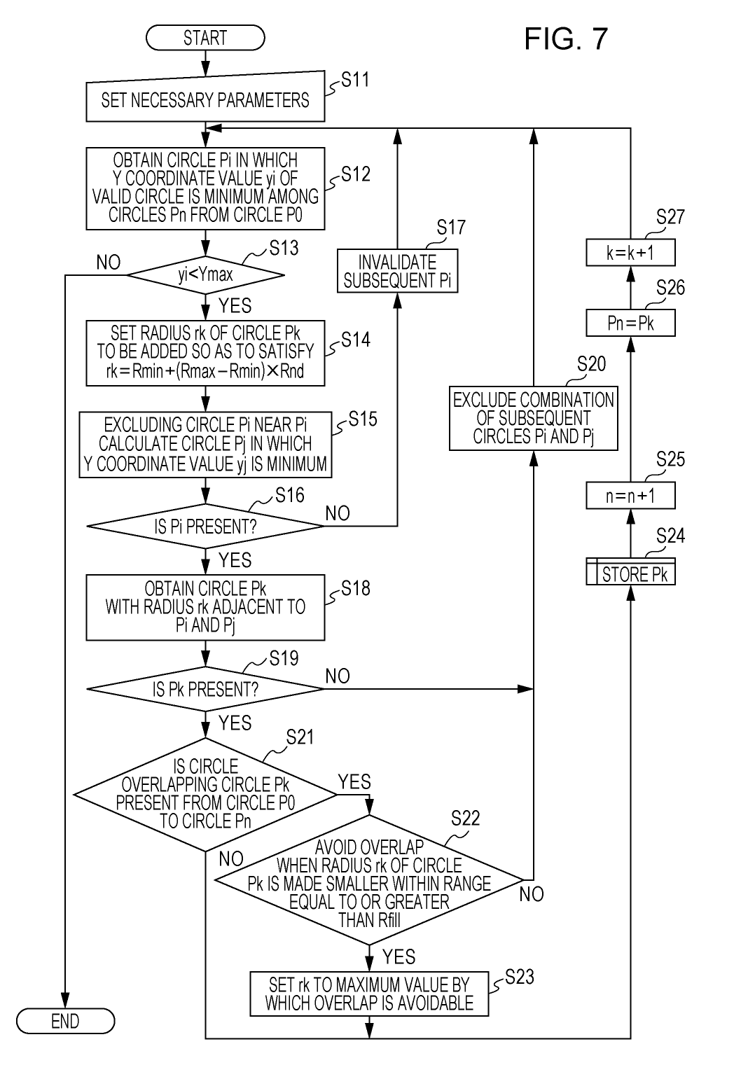

Hereinafter, the algorithm (2) will be described with reference to the flowchart of FIG. 7.

First, in step S11, the necessary parameters described in the algorithm (2) are set. Next, in step S12, a circle Pi of which the Y coordinate value yi is the minimum is obtained from the circle P0 to the circle Pn generated in the above-described in algorithm (1). Next, in step S13, it is determined whether an expression of “yi<Ymax” is satisfied. When it is determined in step S13 that the expression of “yi<Ymax” is not satisfied (No), the process ends. On the other hand, when it is determined in step S13 that the expression of “yi<Ymax” is satisfied (Yes), a radius rk of a circle Pk to be added is set to “rk=Rmin+(Rmax−Rmin)×Rnd” in step S14. Next, in step S15, a circle Pj of which the Y coordinate value yi is the minimum is obtained near the circle Pi except for the circle Pi.

Next, in step S16, it is determined whether the minimum circle Pi is present. When it is determined in step S16 that the minimum circle Pi is not present, the subsequent circle Pi is invalidated in step S17. On the other hand, when it is determined in step S16 that the minimum circle Pi is present, a circle Pk with a radius rk adjacent to circles Pi and Pj is obtained in step S18.

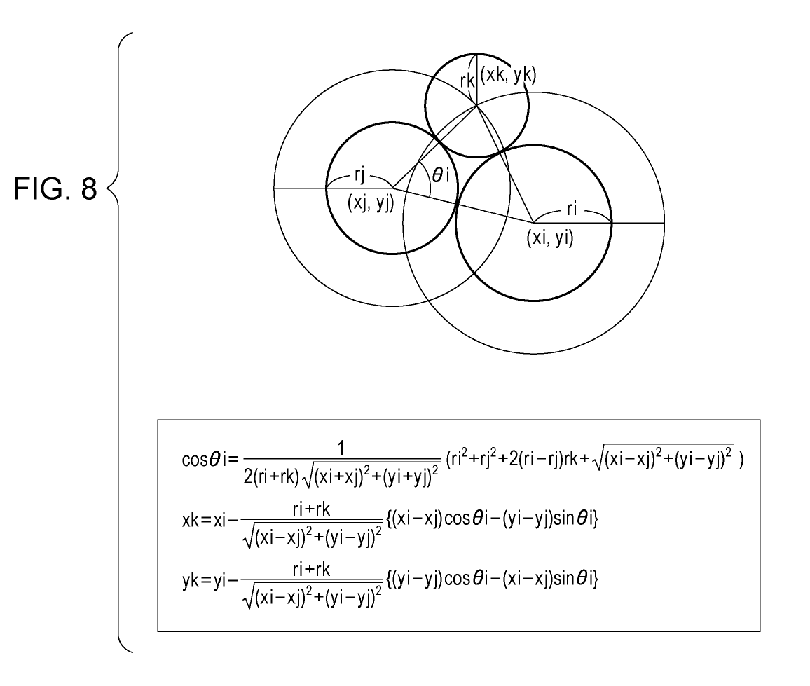

FIG. 8 is a diagram illustrating a method of calculating the coordinates of a circle with an arbitrary radius when the circle is disposed so as to be adjacent to two adjacent circles in step S18.

Next, in step S19, it is determined whether the circle Pk with the radius rk adjacent to the circles Pi and Pj is present. When it is determined in step S19 that the circle Pk is not present, a combination of the subsequent circles Pi and Pj is excluded in step S20. On the other hand, when it is determined in step S19 that the circle Pk is present, it is determined in step S21 whether a circle overlapping the circle Pk is present from the circle P0 to the circle Pn. When it is determined in step S21 that the circle overlapping the circle Pk is not present, the circle Pk (xk, yk, rk) is stored in step S24. Next, in step S25, the value of n increases. In step S26, an expression of “Pn=Pk” is set. In step S27, the value of k increases and the process proceeds to step S12.

On the other hand, when it is determined in step S21 that the circle overlapping the circle is present, it is determined in step S22 whether the overlap is avoidable when the radius rk of the circle Pk is made to be small within the range equal to or greater than Rfill. When it is determined in step S22 that the overlap is not avoidable, the combination of the subsequent circles Pi and Pj is excluded in step S20. On the other hand, when it is determined in step S22 that the overlap is avoidable, the radius rk is set to the maximum value by which the overlap is avoidable. Next, in step S24, the circle Pk (xk, yk, rk) is stored. Next, in step S25, the value of n increases. In step S26, the expression of “Pn=Pk” is set. In step S27, the value of k increases and the process proceeds to step S12.

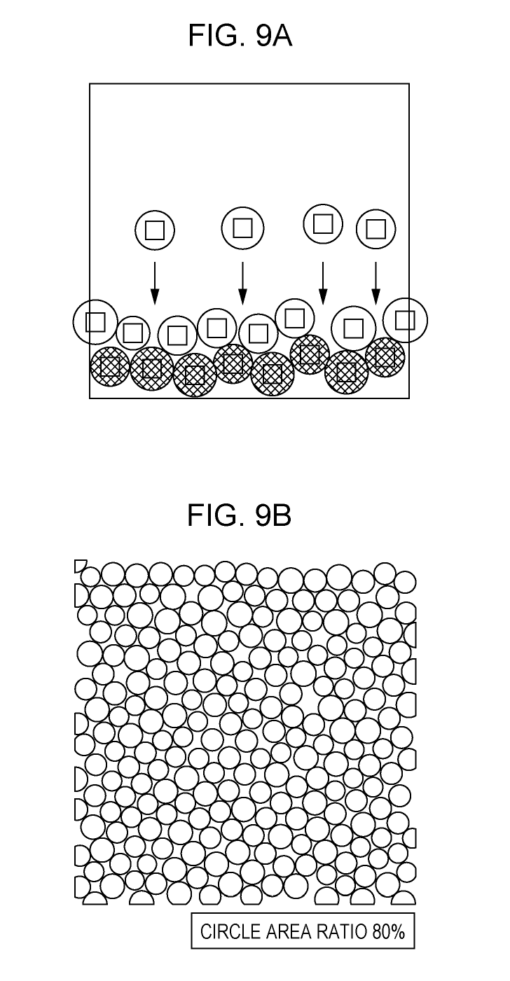

FIG. 9A is a schematic diagram illustrating an image of the method of generating the random pattern. FIG. 9B is a diagram illustrating an example of the method of generating the random pattern in which the area ratio of a circle is 80%. As shown in FIG. 9A, a high-density random pattern can be generated with regularity by changing the range (Rmin to Rmax) in which the radius of the circle is set and files the circles.

Next, after the random pattern is generated, the hole pattern and the groove pattern are generated in the electrode region and the insulation regions, respectively, based on the random pattern.

### Method of Generating Pattern of Electrode Region

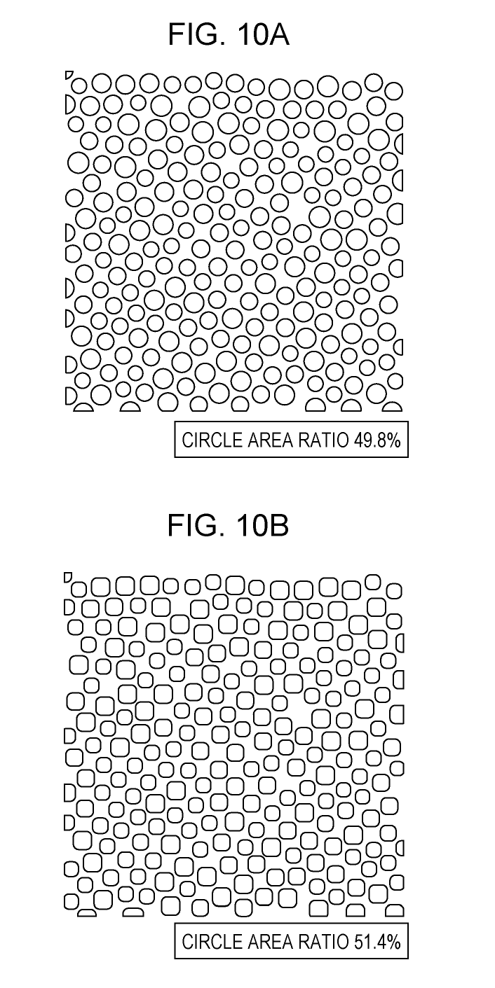

As shown in FIG. 10A, the radii of the circles of the generated random pattern are reduced. Further, as shown in FIG. 10B, an arbitrary figure with, for example, a chamfered square pattern is drawn inside the circle of the generated random pattern. In this way, the isolated random patterns are generated and the random pattern of the electrode region 15 shown in FIG. 2A is obtained by setting the isolated random patterns as the hole patterns 15a in the electrode region 15.

Examples of the figure drawn inside the circle of the generated random pattern include a circle, an ellipse, a polygon, and an indefinite shape. The tendency of the pattern can be changed or the occupation ratio (the coverage ratio of the transparent conductive film 13) can be adjusted by selecting the figure shape.

### Method of Generating Pattern of Insulation Region

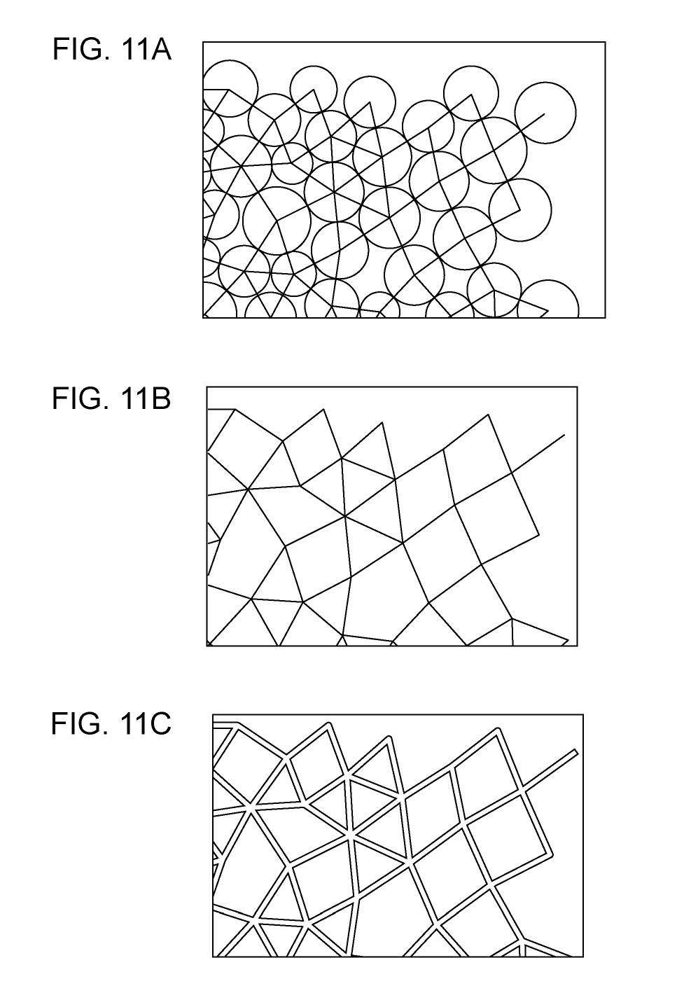

As shown in FIG. 11A, straight lines are drawn so as to bind the centers of the circles of which the outer circumferences are tangent to each other. In this way, as shown in FIG. 11B, polygonal random patterns are formed by line segments extending in random directions. Next, as shown in FIG. 11C, the random patterns of the insulation region 17 are obtained by thickening the line segments of the polygonal random patterns and setting the thickened line segments as the groove patterns 17a in the insulation region 17 shown in FIG. 2A.

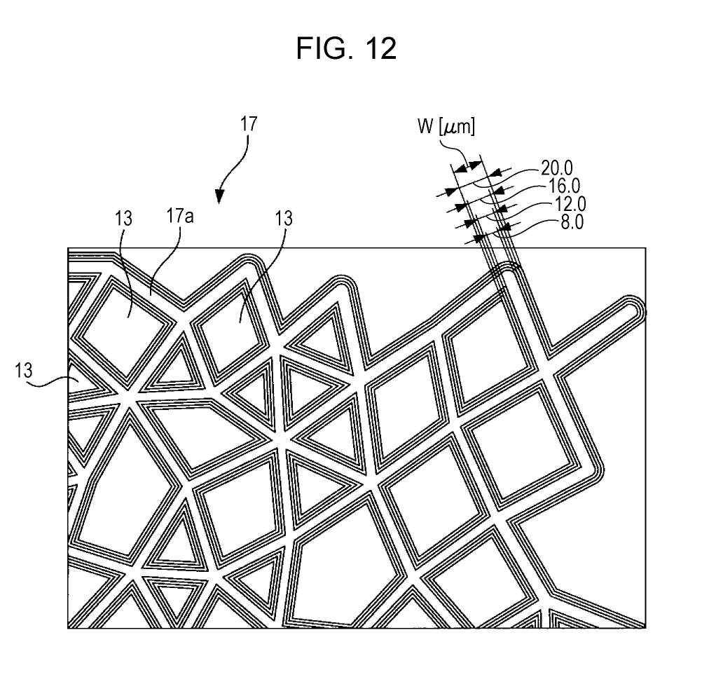

As shown in FIG. 12, the groove patterns 17a can be changed so as to have various line widths W. By changing the line widths W of the groove patterns 17a, the coverage ratio of the insulation region 17 formed using the transparent conductive film 13 separated by the groove patterns 17a can be adjusted in a broad range. Table 1 below shows the calculation result of the coverage ratio [%] of the transparent conductive film 13 in the insulation region 17 for the range (Rmin-Rmax) of the radii r of the circles generated as the random patterns and the respective line widths W of the groove patterns 17a.

TABLE 1

| Line Width | Coverage Ratio [%] | | |
|---|---|---|---|
| W [μm] | r = 25 to 45 [μm] | r = 20 to 35 [μm] | r = 20 to 25 [μm] |
| 8 | 74.9 | 68.9 | 65.5 |
| 12 | 64.0 | 55.8 | 51.2 |
| 16 | 54.0 | 44.4 | 38.8 |
| 20 | 45.1 | 34.6 | 28.5 |

As shown in Table 1 above, it can be understood that the coverage ratio of the transparent conductive film 13 can be adjusted in a broad range of 28.5% to 74.9% in the insulation region 17 where the transparent conductive film 13 is separated by the groove patterns 17a.

On the other hand, for example, when the reverse pattern of the electrode region 15 shown in FIG. 2A is set to the insulation region 15, the upper limit value of the coverage ratio of the transparent conductive film 13 in the insulation region is calculated to about 65% through the following calculation.

That is, when circles are arranged in a given region, the maximum filling ratio of the circles is 90.7% theoretically in a state where the circles are arranged in a zigzag shape. Here, when the radius of the circle is 50 μm and a gap between the circles is set to 8 μm to arrange the circles independently, the radius of each circle is reduced to (50-8/2=)46 μm. In this state, the circle area ratio is equal to (46×46)/(50×50)=0.846, and thus the filling ratio of the circles is (90.7%)×(0.846)=76.7%.

Here, when the radius of each circle is set at random, the gap between the circles is larger and the actual filling ratio is a value between the filling ratio (90.7%) in the zigzag arrangement and the filling ratio (78.5%) in a lattice arrangement. This value is about the maximum 80% even though this value is changed due to a ratio (distribution) between the maximum radius and the minimum radius of the circles.

Therefore, the range of the radius r of the circle initially generated as the random pattern is set to a range of “Rmin=35 μm” to “Rmax=50 μm” and the gap between the circles is set to 8 μm. In this case, the filling ratio of the circles is in the range of “80%×(31×31)/(35×35)=62.76%” to “80% (46×46)/(50×50)=67.71%.” Even when the distribution of the circles generated at random is shifted to a slightly larger circle, the filing ratio of about 65% is derived as the limit value. The limit value of about 65% calculated in this way is less than the coverage ratio 74.9% calculated in the insulation region 17 where the transparent conductive film 13 is separated by the groove patterns 17a.

### 4. First Method of Manufacturing Transparent Electrode Element

### Method of Using Original Disk

Next, a method of manufacturing the transparent electrode element described in the first and second embodiments using the original disk as a first manufacturing method will be described.

### Original Disk

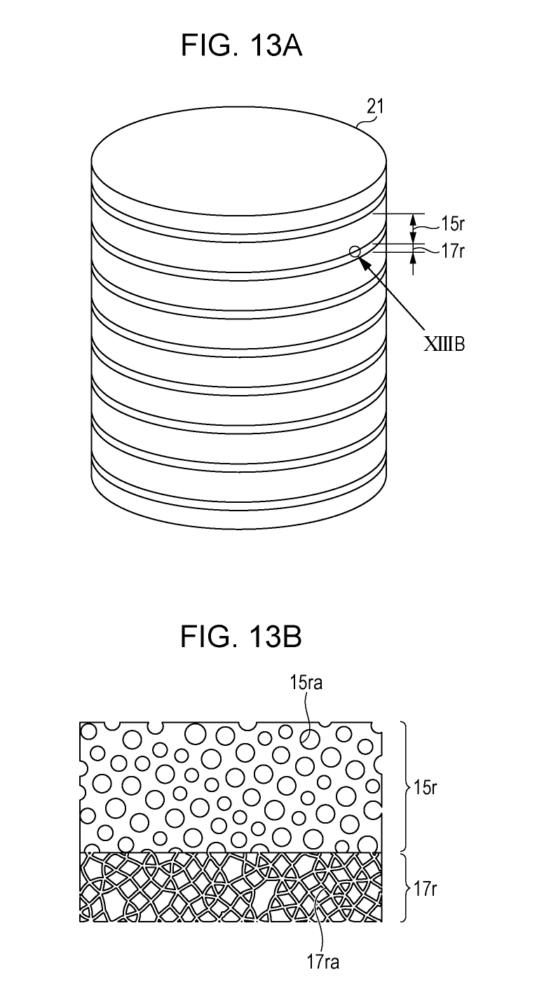

FIG. 13A is a perspective view illustrating an example of the shape of the original disk used in the first manufacturing method. FIG. 13B is an expanded plan view illustrating a part (expanded section XIIIB) of an electrode-region-formed section 15r and an insulation-region-formed section 17r shown in FIG. 13A. An original disk 21 shown in the drawings is, for example, a roll original disk having a cylindrical surface as a transfer surface. The electrode-region-formed sections 15r and the insulation-region-formed sections 17r can alternately be carpeted in the cylindrical surface.

In the electrode-region-formed section 15r, a plurality of concave hole portions 15ra are formed separately. The hole portion 15ra is a portion in which the hole pattern in the electrode region of the transparent electrode element is printed. In the electrode-region-formed section 15r, a convex portion between the hole portions 15ra is a portion in which the transparent conductive film disposed in the electrode region is printed. When the original disk 21 is an original disk used to manufacture the transparent electrode element 2 described with reference to FIGS. 3A and 3B, no hole portion 15ra is disposed in the electrode-region-formed section 15r and the electrode-region-formed section 15r may be configured as a print surface with the same height.

In the insulation-region-firmed section 17r, concave groove portions 17ra extend in random directions. The groove portion 17ra is a portion in which the groove pattern in the insulation region of the transparent electrode element is printed. A convex portions having an island shape and separated by the groove portions 17ra in the insulation-region-formed section 17r is a portion in which the transparent conductive film disposed in an independent island shape in the insulation region is printed. The concave portion is a portion which has the same height as that of the convex portion of the electrode-region-formed section 15r.

### Manufacturing Sequence of Transparent Electrode Element

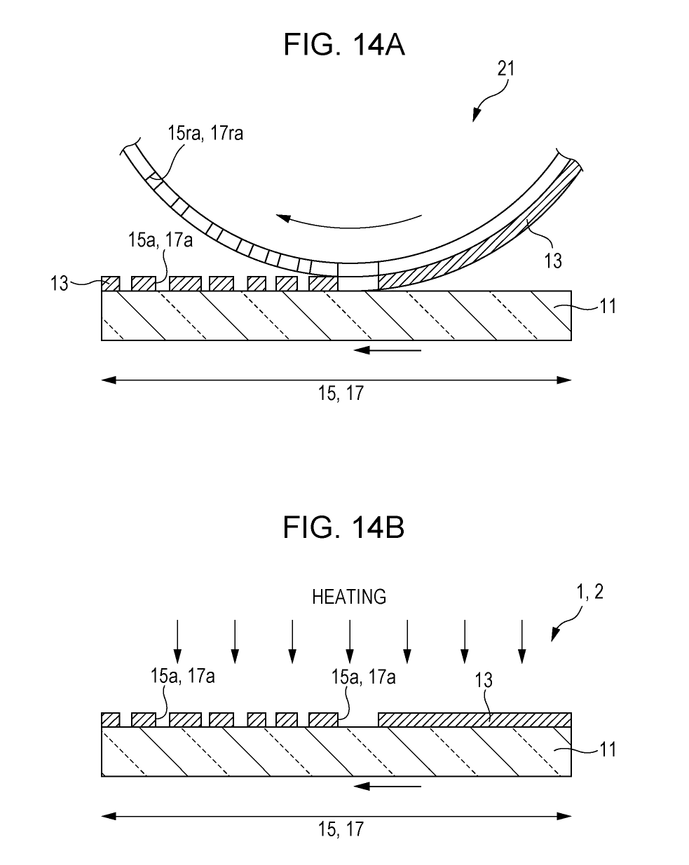

FIGS. 14A and 14B are sectional views illustrating steps of the first method of manufacturing the transparent electrode element using the above-described original disk 21. Next, the sequence of the first manufacturing method will be described with reference to FIGS. 14A and 14B.

As shown in FIG. 14A, conductive ink is applied to the transfer surface of the original disk 21 and the applied conductive ink is printed on the surface of the base substrate 11. Examples of the printing method include screen printing, waterless lithographic printing, flexographic printing, gravure printing, gravure-offset printing, and reverse offset printing. Next, as shown in FIG. 14B, the conductive ink is dried and/or burned at high temperature by heating the conductive ink printed on the surface of the base substrate 11, as necessary. In this way, the desired transparent electrode element 1 of the first embodiment and the desired transparent electrode element 2 of the second embodiment can be obtained.

### 5. Second Method of Manufacturing Transparent Electrode Element

### Method of Applying Pattern Etching

Next, a method of applying pattern etching will be described as the second method of manufacturing the transparent electrode element described in the first and second embodiments.

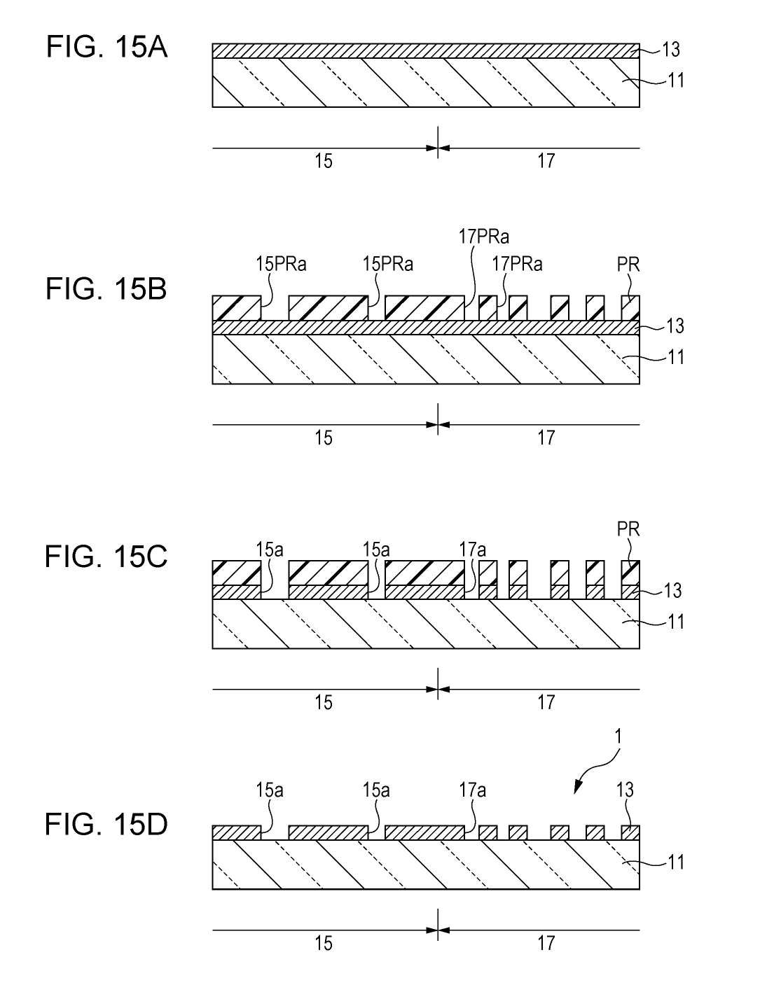

First, as shown in FIG. 15A, the transparent conductive film 13 is formed on the surface of the base substrate 11 in which the electrode region 15 and the insulation region 17 are formed. As a method of forming the transparent conductive film 13, one of a chemical vapor deposition (CVD) method and a physical vapor deposition (PVD) method is selected between depending on the material of the transparent conductive film. As the CVD method, a heat CVD method, a plasma CVD method, an optical CVD method, or the like is applied. As the PVD method, a vacuum deposition method, a plasma-aided deposition method, a sputtering method, an ion plating method, or the like is applied. To form the transparent conductive film 13, the base substrate 11 may be heated, as necessary.

Next, an annealing process is performed on the transparent conductive film 13, as necessary. Thus, the transparent conductive film 13 becomes a state in which amorphous and multi-crystal mixed states are mixed or a multi-crystal state, thereby improving the conductivity of the transparent conductive film 13.

Subsequently, as shown in FIG. 15B, resist patterns PR are formed on the surface of the transparent conductive film 13 by a lithographic method. The resist patterns PR include a plurality of independent hole patterns 15PRa in a section corresponding to the electrode region 15 and include groove patterns 17PRa extending in respective directions in a section corresponding to the insulation region 17. The hole pattern 15PRa is formed to correspond to the hole pattern formed in the transparent conductive film 13 of the electrode region 15. Further, the groove pattern 17PRa is formed to correspond to the groove pattern formed in the transparent conductive film 13 of the insulation region 17. When the transparent electrode element 2 described with reference to FIGS. 3A and 3B is manufactured, no hole pattern is formed in the section corresponding to the electrode region 15. The section corresponding to the electrode region 15 is covered with the resist patterns PR.

A the resist material of the above-described resist pattern PR, for example, one of an organic-based resist and an inorganic-based resist may be used. As the organic-based resist, for example, a novolac-based resist or a chemically amplified resist can be used. Further, as the inorganic-based resist, for example, a metal compound formed by at least one kind of transition metal can be used.

Next, as shown in FIG. 15C, the transparent conductive film 13 is pattern-etched using the resist pattern PR as a mask. Then, the hole patterns 15a are formed in the transparent conductive film 13 in the electrode region 15 and the groove patterns 17a are formed in the transparent conductive film 13 in the insulation region 17. For example, dry etching or wet etching may be used as the pattern etching of the transparent conductive film 13, but it is desirable to use the wet etching since installation is simpler. Further, when the resist patterns PR have no hole pattern in the section corresponding to the electrode region 15, no hole pattern 15a is formed in the transparent conductive film 13 in the electrode region 15.

Thereafter, as shown in FIG. 15D, the resist patterns PR formed in the transparent conductive film 13 are peeled by an ashing process to obtain the desired transparent electrode element 1 (or the transparent electrode element 2 of the second embodiment) of the first embodiment.

### 6. Modifications 1 to 4 of Transparent Electrode Element

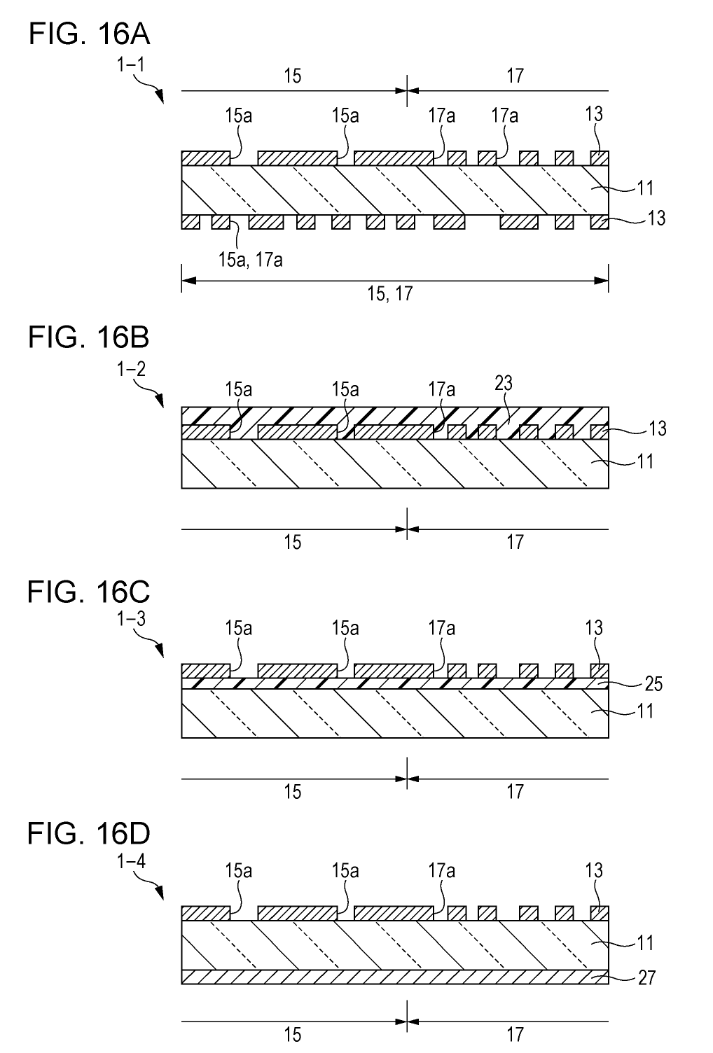

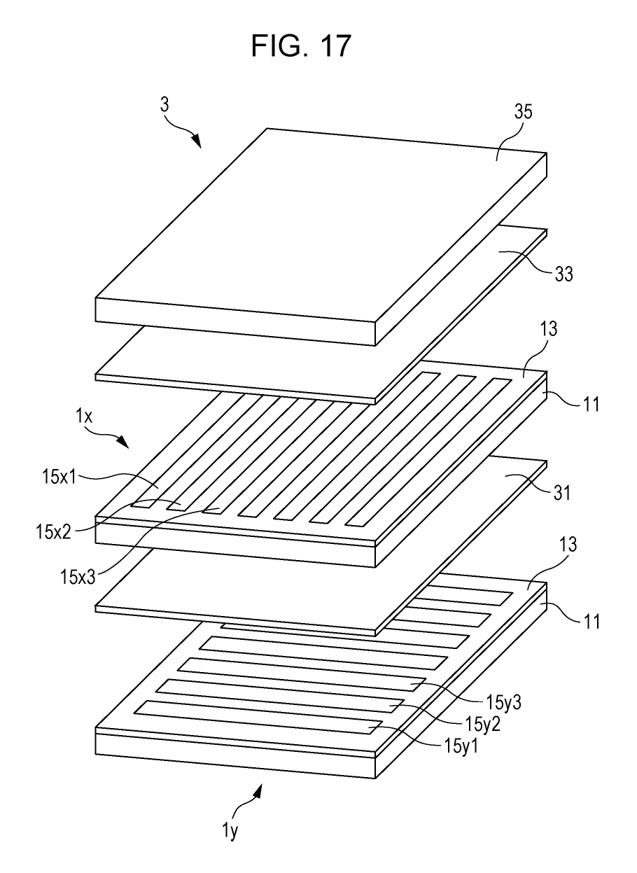

FIGS. 16A to 16D are sectional views illustrating transparent electrode elements according to Modifications 1 to 4 of the transparent electrode element of the embodiment of the present technology. Hereinafter, the transparent electrode element according to each modification will be described with reference to the drawings. FIGS. 16A to 16D show the configurations to which the modifications of the transparent electrode element 1 according to the first embodiment are applied. However, the modifications may also be applied to the transparent electrode element 2 according to the second embodiment.

### Modification 1

FIG. 16A shows the configuration of a transparent electrode element 1-1 including transparent conductive films 13 formed on both surfaces of the base substrate 11 according to Modification 1 of the transparent electrode element. The transparent conductive films 13 in which the electrode region 15 and the insulation region 17 are set are formed on both surfaces of the base substrate 11. Here, for example, the electrode regions 15 are arranged in the x direction on a first surface of the base substrate 11 and the insulation region 17 is arranged in a state where the electrode regions 15 are embedded. On the other hand, the electrode regions 15 are arranged in the y direction on a second surface of the base substrate 11 and the insulation region 17 is arranged in a state where the electrode regions 15 are embedded.

In this way, the transparent electrode element 1-1, in which the electrode regions 15 are arranged in the x and y directions with the base substrate 11 interposed therebetween, can be used as an information input device, as described later. Further, when Modification 1 is applied to the transparent electrode element of the second embodiment described with reference to FIGS. 3A and 3B, the transparent conductive film 13 may be formed as a solid film in the electrode regions 15 on at least one surface of the base substrate 11.

### Modification 2

FIG. 16B shows the configuration of a transparent electrode element 1-2 in which a hard coat layer 23 covering the transparent conductive film 13 is formed according to Modification 2 of the transparent electrode element. When the base substrate 11 is formed of plastic, the hard coat layer 23 is used to prevent damage to the base substrate 11, provide chemical resistance, and precipitate a low-molecular-weight substance in a manufacturing process and to protect the transparent conductive film 13.

As the material of the hard coat layer 23, it is desirable to use an ionizing radiation-curable resin cured by light or an electron beam or a thermal curable resin cured by heating and it is the most desirable to use a light-sensitive resin cured by ultraviolet. As the light-sensitive resin, an acrylate-based resin such as urethane acrylate, epoxy acrylate, polyester acrylate, polyol acrylate, polyether acrylate, or melamine acrylate can be used. For example, a urethane acrylate resin can be obtained by reacting acrylate with hydroxyl or methacrylate-based monomer to a product obtainable by reacting isocyanate monomer or prepolymer to polyester polyol. The thickness of the hard coat layer 23 is preferably in the range of 1 μm to 20 μm, but the embodiment of the present technology is not limited thereto.

The hard coat layer 23 is formed by coating a hard coat material on the base substrate 11. The coating method is not particularly limited and a general coating method can be used. Examples of the existing coating method include a micro gravure coating method, a wire bar coating method, a gravure coating method, a die coating method, a dip method, a spray coating method, a reverse roll coating method, a curtain coating method, a comma coating method, a knife coating method, and a spin coating method. The hard coat material contains a resin raw material such as a bifunctional or higher monomer and/or oligomer, a photopolymerization initiator, and a solvent. The solvent is volatilized by drying the hard coat material coated on the base substrate 11. Thereafter, the hard coat material dried on the base substrate 11 is cured, for example, by emission of ionizing radiation or heating and is formed as the hard coat layer 23.

In this way, the hard coat layer 23 may be formed on the surface of the base substrate 11 on which the transparent conductive film 13 is not formed.

### Modification 3

FIG. 16C shows the configuration of a transparent electrode element 1-3 in which an underlying layer 25 is formed between the base substrate 11 and the transparent conductive film 13 according to Modification 3 of the transparent electrode element. The underlying layer 25 has, for example, an optical adjustment function or an adhesion auxiliary function.

The underlying layer 25 having the optical adjustment function is a layer that assists the non-visibility of the hole patterns 15a or the groove patterns 17a formed in the transparent conductive film 13. The underlying layer 25 having the optical adjustment function is a layer which include two or more laminated layers with different refractive indexes and in which the layer on the side of the transparent conductive layer 13 has a lower refractive index. More specifically, for example, an existing optical adjustment layer can be used. As the optical adjustment layer, for example, a layer disclosed in Japanese Unexamined Patent Application Publication No. 2008-98169, Japanese Unexamined Patent Application Publication No. 2010-15861, Japanese Unexamined Patent Application Publication No. 2010-23282, or Japanese Unexamined Patent Application Publication No. 2010-27294 can be used.

The underlying layer 25 having the adhesion auxiliary function is a layer that ensures the adhesion between the base substrate 11 and the transparent conductive film 13. The underlying layer 25 having the adhesion auxiliary function is formed of, for example, a polyacryl-based resin, a polyamide-based region, a polyamide-imide-based resin, a polyester-based resin, or a hydrolysis/dehydration condensation product such as a metal element chloride, peroxide, or alkoxide.

When it is desired to ensure the adhesion between the base substrate 11 and the transparent conductive film 13, a process of assisting the adhesion may be performed on the surface of the base substrate 11 on which the transparent conductive film 13 is formed without forming the underlying layer 25. Examples of this process include a discharge process for radiation of glow discharge or corona discharge and a chemical process using acid or alkali. Further, after the transparent conductive film 13 is formed, a calendar process may be performed to improve the adhesion.

### Modification 4

FIG. 16D shows the configuration of a transparent electrode element 1-4, in which a shield layer 27 is formed on the surface opposite to the surface of the base substrate 11 on which the transparent conductive film 13 is formed, according to Modification 4 of the transparent electrode element. The shield layer 27 is a layer that reduces noise caused due to the electromagnetic waves in the electrode region 15 formed using the transparent conductive film 13.

As the material of the shield layer 27, the same material as that of the transparent conductive film 13 can be used. As a method of forming the shield layer 27, the same method as the method of forming the transparent conductive film 13 can be used. However, the shield layer 27 is not patterned and is formed on the entire surface of the base substrate 11.

### 7. Third Embodiment

### Information Input Device Using Transparent Electrode Element

FIG. 17 is a diagram illustrating the configuration of the main units of an information input device including the transparent electrode element. An information input device 3 shown in the drawing is, for example, an electrostatic capacitance type touch panel which is disposed on the display surface of a display panel. The information input device 3 includes two transparent electrode elements 1x and 1y. Each of the transparent electrode elements 1x and 1y is one of the transparent electrode element described with reference to FIGS. 2A and 2B in the first embodiment, the transparent electrode element described with reference to FIGS. 3A and 3B in the second embodiment, and the transparent electrode elements of Modifications 2 to 4.

In the transparent electrode elements 1x and 1y, electrode regions 15x1, 15x2, etc. and electrode regions 15y1, 15y2, etc. are arranged in parallel on the base substrate 11, respectively. In the transparent electrode elements 1x and 1y, the electrode regions 15x1, 15x2, etc. and electrode regions 15y1, 15y2, etc. are arranged so as to be perpendicular to each other in the x and y directions and are bonded to each other with an adhesive insulation film 31 interposed therebetween. Further, in a changed configuration in which the two transparent electrode elements 1x and 1y are bonded together, as described in Modification 1, the transparent electrode element 1-1 including the transparent conductive films 13 arranged on both surfaces of the base substrate 11 may be used.

Although not illustrated in the drawing, it is assumed that a plurality of terminals used to individually apply a measurement voltage are wired in the electrode regions 15x1, 15x2, etc. and 15y1, 15y2, etc. of the transparent electrode elements 1x and 1y in the information input device 3.

An optical layer 35 may be disposed on the transparent electrode element 1x on the side of an information input surface of the information input device 3 with an adhesive layer 33 interposed therebetween, as necessary. The adhesive layer 33 and the optical layer 35 are formed of a transparent material. Instead of the optical layer 35, a ceramic coat (overcoat) layer such as an oxide silicon (SiO₂) film may be formed.

In the information input device 3 with the above-described configuration, the measurement voltage is applied alternately to the electrode regions 15x1, 15x2, etc. arranged in the transparent electrode element 1x and the electrode regions 15y1, 15y2, etc. arranged in the transparent electrode element 1y. In this state, when a finger or a touch pen is touched on the surface of the base substrate 11, the capacitance of each portion in the information input device 3 is varied, and thus the measurement voltages of the electrode regions 15x1, 15x2, etc and 15y1, 15y2, etc are varied. The variation is different in accordance with the distance from the location touched by the finger or the touch pen and is the largest at the location where the finger or the touch pen is touched. Therefore, the location in which the variation in the measurement voltage is the largest and which is addressed by the electrode regions 15xn and 15yn is detected as the location where the finger or the touch pen is touched.

### Advantages of Third Embodiment

In the information input device 3 described in the third embodiment, the transparent electrode elements 1x and 1y described in the first and second embodiments and the modifications are used. In this way, it is possible to reduce the visibility of the electrode regions 15x1, 15x2, etc. and 15y1, 15y2, etc. up to the limit. Thus, as described later, when the information input device 3 is disposed on the display surface of a display panel, it is possible to prevent the patterns of the electrode regions 15x1, 15x2, etc. and 15y1, 15y2, etc. of the information input device 3 from affecting the display characteristics of the display panel.

In the third embodiment, the configuration of the information input device 3 including the two transparent electrode elements 1x and 1y has been described. However, the information input device according to embodiments of the present technology is not limited to the configuration, but may be broadly applied to an information input device including the transparent electrode element. For example, the transparent electrode elements may have a configuration in which the electrode regions 15x1, 15x2, etc. and 15y1, 15y2, etc. are arranged in an insulated state on the same surface of one base substrate 11. Even in this configuration, the same advantages as those of the information input device 3 of the third embodiment can be obtained.

### 8. Fourth Embodiment

### Display Apparatus Using Information Input Device

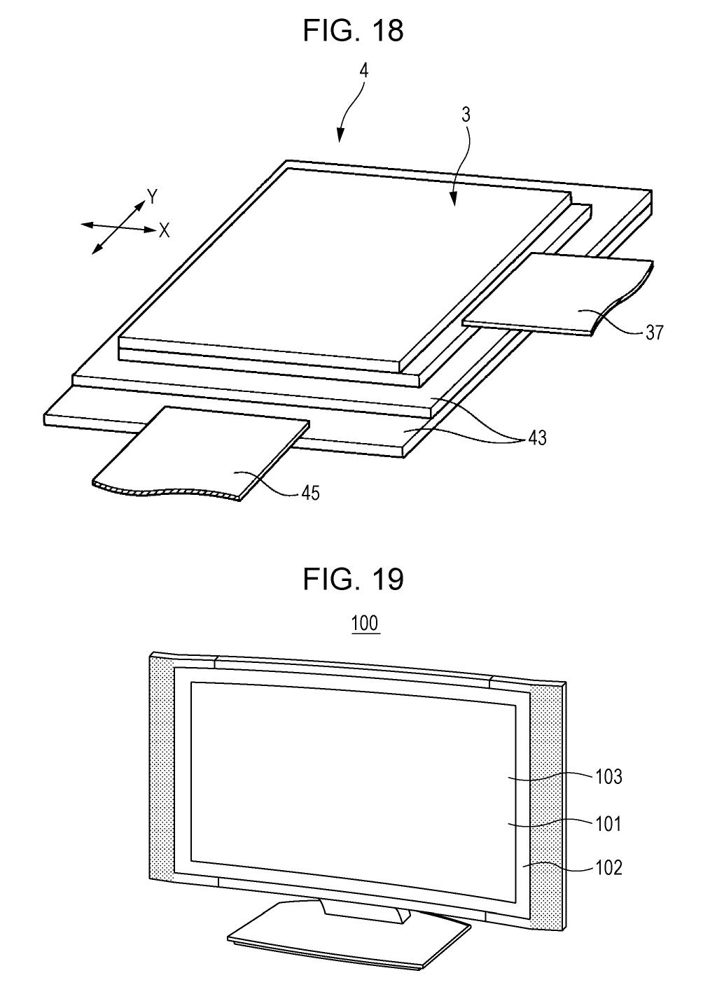

FIG. 18 is a perspective view illustrating a display apparatus including the information input device as an example of an electronic apparatus according to an embodiment of the present technology. In a display apparatus 4 shown in the drawing, the information input device 3 having, for example, the configuration described in the third embodiment is disposed on the display surface of a display panel 43.

The display panel 43 is not particularly limited. For example, various flat surface type display apparatuses such as a liquid crystal display, a plasma display panel (PDP), an electro-luminescence (EL) display, and a surface-conduction electron-emitter display (SED) can be used as the display panel 43. Further, a CRT (Cathode Ray Tube) display may be used.

For example, a flexible print substrate 45 is connected to the display panel 43 so that a signal of a display image is input.

The information input device 3 is superimposed on the image display surface of the display panel 43 so as to cover the display surface. A flexible print substrate 37 is connected to the information input device 3, and thus the above-described measurement voltage is applied from the flexible print substrate 37 to the electrode regions 15x1, 15x2, etc. and 15y1, 15y2, etc. of the information input device 3.

Thus, when a user touches his or her finger or a touch pen on a part of a display image displayed on the display panel 43, information regarding the position of the touched part can be input to the information input device 3.

### Advantages of Fourth Embodiment

In the above-described display apparatus 4 of the fourth embodiment, the information input device 3 having the above-described configuration of the third embodiment is disposed on the display surface of the display panel 43. Therefore, the display of the display panel 43 does not affect the visibility of the electrode regions 15x1, 15x2, etc. and 15y1, 15y2, etc. of the information input device 3. Accordingly, even the information input device 3 is included, a high-definition display of the display panel 43 can be ensured.

### 9. Fifth Embodiment

### Application of Electronic Apparatus

FIGS. 19 to 23 are diagrams illustrating examples of the electronic apparatus in which the display apparatus including the information input device described with reference to FIG. 18 in the fourth embodiment is applied to a display unit. Hereinafter, application examples of the electronic apparatus according to an embodiment of the present technology will be described.

FIG. 19 is a perspective view illustrating a television to which an embodiment of the present technology is applied. A television 100 according to the application example includes a display unit 101 formed of a front panel 102 or a filter glass 103. The display apparatus described above is applied as the display unit 101.

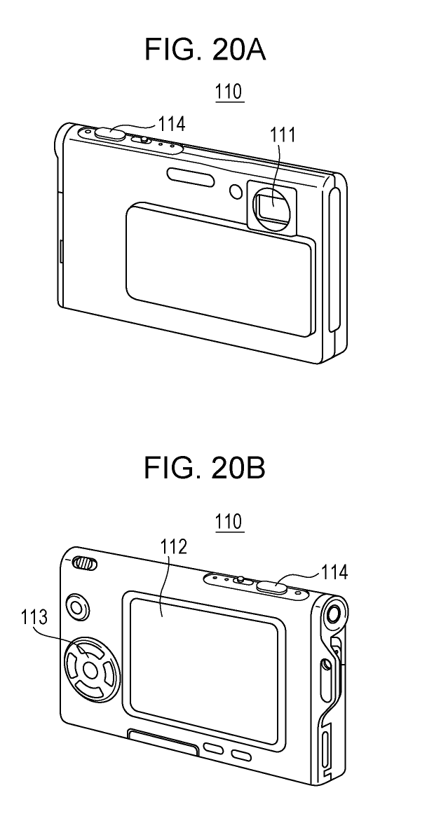

FIGS. 20A and 20B are diagrams illustrating a digital camera to which an embodiment of the present technology is applied. FIG. 20A is a perspective view illustrating the digital camera viewed from the front side and FIG. 20B is a perspective view illustrating the digital camera viewed from the rear side. A digital camera 110 according to the application example includes a flash light-emitting unit 111, a display unit 112, a menu switch 113, and a shutter button 114. The display apparatus described above is applied as the display unit 112.

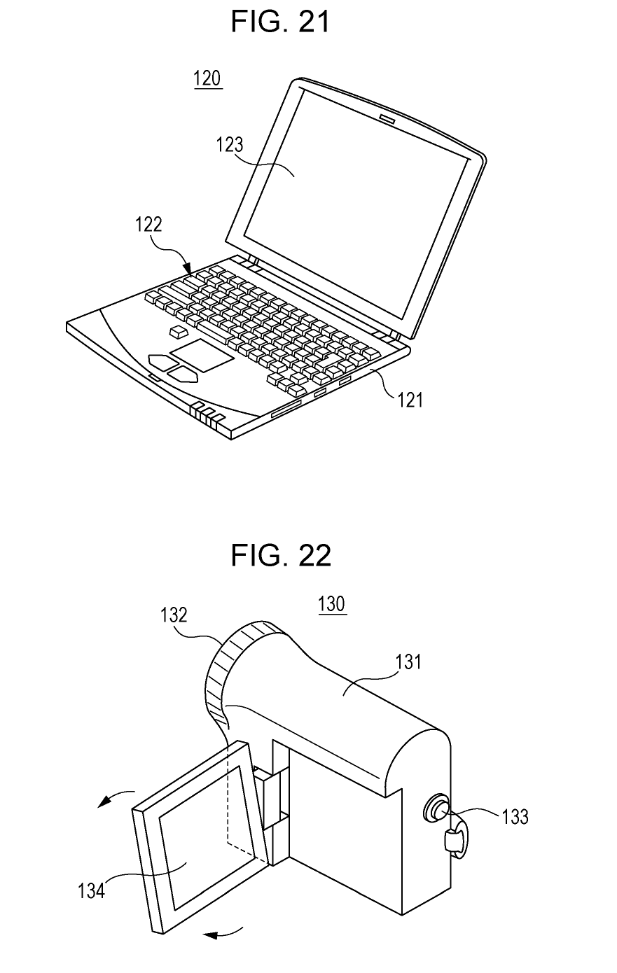

FIG. 21 is a perspective view illustrating a notebook-type personal computer to which an embodiment of the present technology is applied. A notebook-type personal computer 120 according to this application example includes a main body 121, a keyboard 122 operated when characters or the like are input, and a display unit 123 displaying an image. The display apparatus described above is applied as the display unit 123.

FIG. 22 is a perspective view illustrating a video camera to which an embodiment of the present technology is applied. A video camera 130 according to the application example includes a main body unit 131, a subject imaging lens 132 facing the front side, a photographing start/stop switch 133, and a display unit 134. The display apparatus described above is applied as the display unit 134.

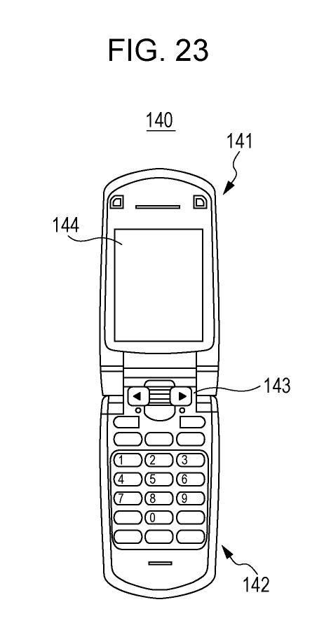

FIG. 23 is a front view illustrating a portable terminal apparatus such as a cellular phone to which an embodiment of the present technology is applied. A cellular phone 140 according to the application includes an upper-side casing 141, a lower-side casing 142, a connection unit (here, a hinge unit) 143, and a display unit 144. The display apparatus described above is applied as the display unit 144.

### Advantages of Fifth Embodiment

In each electronic apparatus described above in the fifth embodiment, the display apparatus described in the fourth embodiment is used as the display unit. Therefore, even when the information input device 3 is included, a high-definition display of the display panel 43 can be ensured.

### EXAMPLES

Transparent electrode elements according Examples 1 to 3 and a comparative example were manufactured as follows.

A silver nanowire with a diameter of 30 nm and a length of 10 μm to 50 μm was produced by the existing method with reference to the document (“ACS Nano” in 2010, VOL. 4, NO. 5, pp. 2955-2963).

Next, the following material was input along with the manufactured silver nanowire and a dispersion liquid was produced by dispersing the silver nanowire in ethanol:

silver nanowire: 0.28 weight by %,

hydroxypropyl methylcellulose (transparent resin material) produced by Aldrich Co.: 0.83 weight by %,

Duranate D101 (resin curing agent) produced by Asahi Kasel Co.: 0.083 weight by %,

Neostan U100 (curing accelerator catalyst) produced by Nitto Kasel Co.: 0.0025 weight by %, and

ethanol (solvent): 98.8045 weight by %.

A dispersion film was formed by applying the produced dispersion liquid to the transparent base substrate of number 8. A base weight of the silver nanowire was set to about 0.05 g/m². PET (O300E made by Mitsubishi Chemical Corporation) with a film thickness of 125 μm was used as the transparent base substrate. Subsequently, the solvent in the dispersion film was dried and removed by performing a heating process at 85° C. for 2 minutes in the atmosphere. Subsequently, the transparent resin material in the dispersion film was cured by performing a heating process at 150° C. for 30 minutes in the atmosphere, and thus a silver nanowire layer was obtained as the transparent conductive film. The sheet resistance of a transparent conductive film including the silver nanowire obtained in this way was 100Ω/□.

Next, a resist layer was formed on the silver nanowire of the transparent conductive film, and then pattern exposure was performed on the electrode region and the insulation region of the silver nanowire using a Cr photomask formed in a random pattern. At this time, in Examples 1 to 3, the following pattern exposure was performed on the electrode region and the insulation region.

### Example 1

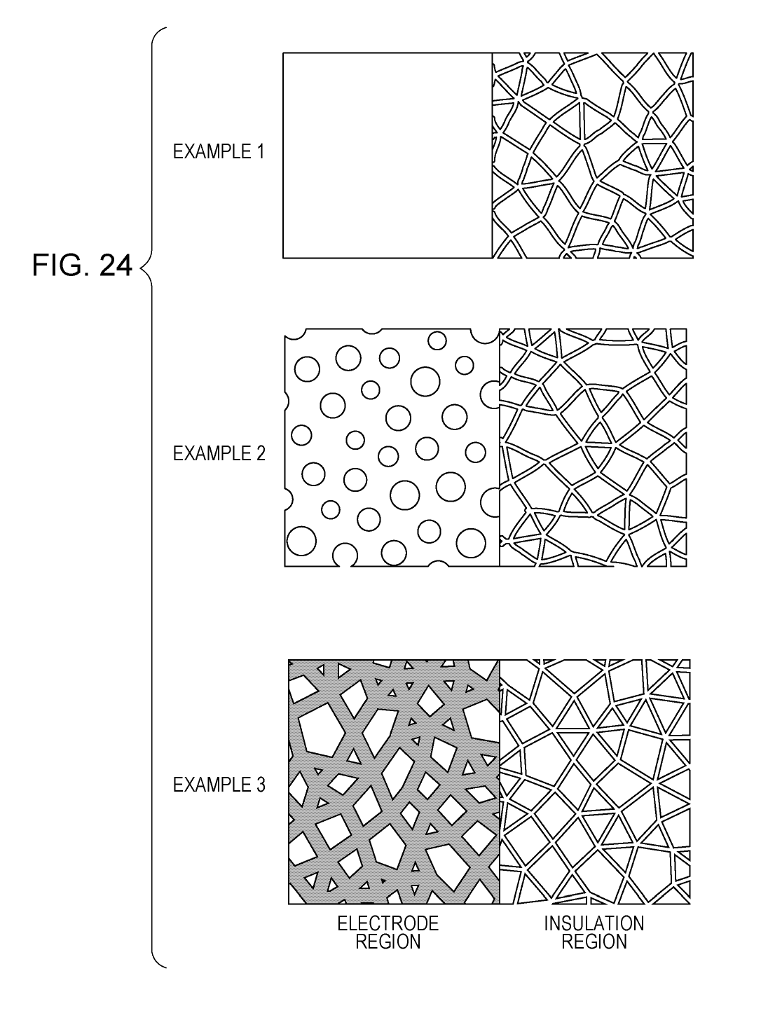

As shown in FIG. 24, the pattern exposure was performed so that a random pattern was formed in the electrode region and a groove pattern was formed as a random pattern in the insulation region. The parameters used when the random pattern was generated was as follows:

electrode region: No; and

insulation region: radius range of 25 μm to 45 μm and line width of groove pattern of 8 μm.

### Example 2

As shown in FIG. 24, the pattern exposure was performed so that a hole pattern was formed as the random pattern in the electrode region and a groove pattern was formed as the random pattern in the insulation region. The parameters used when the random pattern was generated was as follows:

electrode region: radius range of 35 μm to 48 μm and radius reduction value of 18.5 μm; and insulation region: the same as that of Example 1.

### Example 3

As shown in FIG. 24, the pattern exposure was performed so that a strip-shaped pattern was formed as the random pattern in the electrode region and a groove pattern was formed as the random pattern in the insulation region. The parameters used when the random pattern was generated was as follows:

electrode region: radius range of 25 μm to 45 μm and line width with a strip-shaped pattern of 30 μm; and

insulation region: the same as that of Example 1.

### Comparative Example

No random pattern was formed in both the electrode region and the insulation region.

After the pattern exposure was performed in this way, a resist pattern was formed by developing the resist layer and the silver nanowire layer was subjected to wet etching using the resist pattern as a mask. After the etching ends, the resist layer was removed by an ashing process.

In this way, the transparent electrode element including the electrode region and the insulation region with each parameter of the coverage ratio of the transparent conductive film was obtained.

### Evaluation

The non-visibility, the moire and interference light, and dazzle were visually evaluated on the patterns in the electrode region and the insulation region of each of the transparent electrode elements produced in Examples 1 to 3 and the comparative example. The result is shown in Table 2 below together with each parameter of the coverage ratio of the transparent conductive film. The evaluation reference of each item is as follows.

### Non-Visibility

⊙: a pattern is not visible even when the pattern is viewed in any direction;

◯: a pattern can be visible depending on an angle although it is difficult to see the pattern; and

x: a pattern is visible.

### Moire and Interference Light

⊙: moire and interference light is not noticeable even in examination from all angles;

◯: moire and interference light is not noticeable in examination from the front side, but moire and interference light is a little noticeable in inclined examination; and

x: moire and interference light is noticeable in examination from the front side.

### Dazzle

⊙: dazzle is not noticeable even in examination from all angles;

◯: dazzle is not noticeable in examination from the front side, but dazzle is a little noticeable in inclined examination; and

x: dazzle is noticeable in examination from the front side.

TABLE 2

| | Coverage Ratio [%] of Transparent | | | | | |
|---|---|---|---|---|---|---|
| | Conductive Film | | | Non- | Moire and | |
| | Electrode | Insulation | Coverage Ratio | visibility | Interference | |
| | Region | Region | Difference | of Pattern | Light | Dazzle |
| Example 1 | 100.0 | 74.9 | 25.1 | ◯ | ⊙ | ⊙ |
| Example 2 | 74.9 | 74.9 | 0.0 | ⊙ | ⊙ | ⊙ |
| Example 3 | 73.0 | 74.9 | 1.9 | ⊙ | ⊙ | ⊙ |
| Comparative | 100.0 | 0.0 | 100.0 | X | ⊙ | ⊙ |
| Example | | | | | | |

From the result shown in Table 2 above, it was confirmed that the non-visibility of the patterns in the electrode region and the insulation region was satisfactory by forming the transparent conductive film even in the insulation region in Examples 1 to 3. In particular, in Examples 2 and 3, it was confirmed that the non-visibility of the patterns was more satisfactory compared to Example 1 by forming the random pattern even in the transparent conductive film in the electrode region and suppressing a difference in the coverage ratio of the transparent conductive film between the electrode region and the insulation region.

In the electrode region of Examples 2 and 3, a reflection L value of the diffused reflection of outside light on the surface of the silver nanowire was decreased since the coverage ratio of the transparent conductive film formed of the silver nanowire layer was suppressed. As a result, in the configuration in which the transparent electrode element is disposed on the display surface of the display panel, the effect of settling down the black display of a display screen was confirmed when the transparent electrode element of Examples 2 and 3 was used, compared to a case where a straight-line pattern, a diamond pattern, or the like was used. Thus, in the display apparatus in which the touch panel including the transparent electrode element is disposed on the display surface, the effect of improving the display characteristics was obtained.

As an additional example, a process was performed by dipping the silver nanowire layer (the transparent conductive film) with the random pattern obtained in Examples 1 to 3 in a solution in which the colored compound is dissolved and adsorbing a colored compound to the surface of the silver nanowire. By this process, it was confirmed that the reflection L value was further decreased in both the electrode region and the insulation region formed of the silver nanowire layer (the transparent conductive film) of Examples 1 to 3. As a result, it was confirmed that the display characteristics of the display panel could be maintained even in the touch panel disposed on the display surface by using the transparent electrode element, in which the random patterns are formed in the transparent conductive film obtained by adsorbing the colored compound in the metal nanowire, as the touch panel.

The embodiments of the present technology may be realized as follows.

(1) A transparent electrode element includes: a base substrate; a transparent conductive film which is formed on the base substrate; an electrode region which is formed using the transparent conductive film; and an insulation region which is a region adjacent to the electrode region and in which the transparent conductive film is separated in independent island shapes by groove patterns extending in random directions.

(2) In the transparent electrode element described in (1), the transparent conductive film ranging between the electrode region and the insulation region is disposed at random in a boundary between the electrode region and the insulation region.

(3) In the transparent electrode element described in (1) or (2), the groove patterns formed in the insulation region have the same line width.

(4) In the transparent electrode element described in any one of (1) to (3), a plurality of hole patterns are formed randomly in the transparent conductive film forming the electrode region.

(5) In the transparent electrode element described in (4), a plurality of strip-shaped patterns formed of the transparent conductive film are formed in the electrode region so as to extend in random directions and the hole patterns are separated by the strip-shaped patterns.

(6) In the transparent electrode element described in any one of (1) to (5), the base substrate is formed of a transparent material.

(7) An information input device includes: a base substrate; a transparent conductive film which is formed on the base substrate; a plurality of electrode regions which are formed using the transparent conductive film; and an insulation region which is a region adjacent to the plurality of electrode regions and in which the transparent conductive film is separated in independent island shapes by groove patterns extending in random directions.

(8) An electronic apparatus includes: a display panel; a transparent electrode film disposed on a display surface side of the display panel; a plurality of electrode regions formed using the transparent conductive film; and an insulation region which is a region adjacent to the plurality of electrode regions and in which the transparent conductive film is separated in independent island shapes by groove patterns extending in random directions.

The present disclosure contains subject matter related to that disclosed in Japanese Priority Patent Application JP 2011-050060 filed in the Japan Patent Office on Mar. 8, 2011, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A transparent electrode element comprising:
a base substrate;
a transparent conductive film which is formed on the base substrate;
an electrode region which is formed using the transparent conductive film; and
an insulation region which is a region adjacent to the electrode region and in which the transparent conductive film is separated in independent island shapes by groove patterns extending in random directions.

2. The transparent electrode element according to claim 1, wherein the transparent conductive film ranging between the electrode region and the insulation region is disposed at random in a boundary between the electrode region and the insulation region.

3. The transparent electrode element according to claim 1, wherein the groove patterns formed in the insulation region have the same line width.

4. The transparent electrode element according to claim 1, wherein a plurality of hole patterns are formed randomly in the transparent conductive film forming the electrode region.

5. The transparent electrode element according to claim 4, wherein in the electrode region, a plurality of strip-shaped patterns formed of the transparent conductive film are formed so as to extend in random directions and the hole patterns are separated by the strip-shaped patterns.

6. The transparent electrode element according to claim 1, wherein the base substrate is formed of a transparent material.

7. An information input device comprising:
a base substrate;
a transparent conductive film which is formed on the base substrate;
a plurality of electrode regions which are formed using the transparent conductive film; and
an insulation region which is a region adjacent to the plurality of electrode regions and in which the transparent conductive film is separated in independent island shapes by groove patterns extending in random directions.

8. An electronic apparatus comprising:
a display panel;
a transparent electrode film disposed on a display surface side of the display panel;
a plurality of electrode regions formed using the transparent conductive film; and
an insulation region which is a region adjacent to the plurality of electrode regions and in which the transparent conductive film is separated in independent island shapes by groove patterns extending in random directions.
